(19) United States
(12) Patent Application Publication
(10) Pub. No.: US 2020/0152674 A1
(43) Pub. Date: May 14, 2020

(54) IMAGE SENSOR AND METHOD FOR MANUFACTURING IMAGE SENSOR

(71) Applicant: HUAIAN IMAGING DEVICE MANUFACTURER CORPORATION, HUAIAN (CN)

(72) Inventors: Xiaotong CUI, HUAIAN (CN); Weiming ZHONG, HUAIAN (CN); Kishou KANEKO, HUAIAN (CN); Xiaolu HUANG, HUAIAN (CN)

(73) Assignee: HUAIAN IMAGING DEVICE MANUFACTURER CORPORATION, HUAIAN (CN)

(21) Appl. No.: 16/535,568

(22) Filed: Aug. 8, 2019

(30) Foreign Application Priority Data
Nov. 9, 2018 (CN) 201811328089.9

(51) Int. Cl. H01L 27/146

(52) U.S. Cl. CPC H01L 27/1463; H01L 27/14683

(57) ABSTRACT

An image sensor comprising a semiconductor substrate and a trench isolation structure that is formed in the semiconductor substrate, wherein the trench isolation structure sequentially includes, from an outer portion to an inner portion of the trench isolation structure, a first oxide layer, a nitride layer, a second oxide layer and a semiconductor material layer that respectively extend in a thickness direction of the semiconductor substrate, such that a semiconductor-oxide-nitride-oxide-semiconductor structure is formed from the semiconductor substrate to the inner portion of the trench isolation structure via the outer portion of the trench isolation structure.

### CROSS-REFERENCE TO RELATED APPLICATIONS

This application claims priority to Chinese Patent Application No. 201811328089.9, filed on Nov. 9, 2018, which is hereby incorporated by reference in its entirety.

### TECHNICAL FIELD

The present disclosure relates generally to the field of semiconductor technology, and more particularly, to an image sensor and a method for manufacturing an image sensor.

### BACKGROUND

Trench isolation structures (including deep trench isolation (DTI) structures and shallow trench isolation (STI) structures, etc.) are typically formed in CMOS image sensors.

Accordingly, there is a need for new technologies.

### SUMMARY

One of aims of the present disclosure is to provide an image sensor and a method for manufacturing an image sensor.

One aspect of this disclosure is to provide an image sensor, comprising: a semiconductor substrate; and a trench isolation structure that is formed in the semiconductor substrate, wherein the trench isolation structure sequentially includes, from an outer portion to an inner portion of the trench isolation structure, a first oxide layer, a nitride layer, a second oxide layer and a semiconductor material layer that respectively extend in a thickness direction of the semiconductor substrate, such that a semiconductor-oxide-nitride-oxide-semiconductor structure is formed from the semiconductor substrate to the inner portion of the trench isolation structure via the outer portion of the trench isolation structure.

Another aspect of this disclosure is to provide a method for manufacturing the image sensor, comprising: providing a semiconductor substrate; and forming a trench isolation structure in the semiconductor substrate by sequentially forming a first oxide layer, a nitride layer, a second oxide layer and a semiconductor material layer that respectively extend in a thickness direction of the semiconductor substrate, such that a semiconductor-oxide-nitride-oxide-semiconductor structure is formed from the semiconductor substrate to an inner portion of the trench isolation structure via an outer portion of the trench isolation structure.

Further features of the present disclosure and advantages thereof will become apparent from the following detailed description of exemplary embodiments with reference to the attached drawings.

### BRIEF DESCRIPTION OF THE DRAWINGS

The accompanying drawings, which constitute a part of the specification, illustrate embodiments of the present disclosure and, together with the description, serve to explain the principles of the present disclosure.

The present disclosure will be better understood according the following detailed description with reference of the accompanying drawings.

FIG. 1 schematically illustrates a configuration of a conventional image sensor.

FIG. 2 schematically illustrates a configuration of an image sensor according to one or more exemplary embodiments of this disclosure.

FIG. 3 schematically illustrates a configuration of an image sensor according to one or more exemplary embodiments of this disclosure.

FIG. 4 schematically illustrates a configuration of an image sensor according to one or more exemplary embodiments of this disclosure.

FIG. 5 schematically illustrates at least a part of a configuration of an image sensor according to one or more exemplary embodiments of this disclosure.

FIGS. 6A through 6N schematically illustrate respectively a method for manufacturing an image sensor according to one or more exemplary embodiments of this disclosure, in fragmentary cross sections of the image sensor at one or more steps.

FIGS. 7A through 7G schematically illustrate respectively a method for manufacturing an image sensor according to one or more exemplary embodiments of this disclosure, in fragmentary cross sections of the image sensor at one or more steps.

FIGS. 8A through 8E schematically illustrate respectively a method for manufacturing an image sensor according to one or more exemplary embodiments of this disclosure, in fragmentary cross sections of the image sensor at one or more steps.

Note that, in the embodiments described below, in some cases the same portions or portions having similar functions are denoted by the same reference numerals in different drawings, and description of such portions is not repeated. In some cases, similar reference numerals and letters are used to refer to similar items, and thus once an item is defined in one figure, it need not be further discussed for following figures.

In order to facilitate understanding, the position, the size, the range, or the like of each structure illustrated in the drawings and the like are not accurately represented in some cases. Thus, the disclosure is not necessarily limited to the position, size, range, or the like as disclosed in the drawings and the like.

### DETAILED DESCRIPTION

Various exemplary embodiments of the present disclosure will be described in details with reference to the accompanying drawings in the following. It should be noted that the relative arrangement of the components and steps, the numerical expressions, and numerical values set forth in these embodiments do not limit the scope of the present invention unless it is specifically stated otherwise.

The following description of at least one exemplary embodiment is merely illustrative in nature and is in no way intended to limit this disclosure, its application, or uses. That is to say, the structure and method discussed herein are illustrated by way of example to explain different embodiments according to the present disclosure. It should be understood by those skilled in the art that, these examples, while indicating the implementations of the present disclosure, are given by way of illustration only, but not in an exhaustive way. In addition, the drawings are not necessarily drawn to scale, and some features may be enlarged to show details of some specific components.

Techniques, methods and apparatus as known by one of ordinary skill in the relevant art may not be discussed in detail, but are intended to be regarded as a part of the specification where appropriate.

In all of the examples as illustrated and discussed herein, any specific values should be interpreted to be illustrative only and non-limiting. Thus, other examples of the exemplary embodiments could have different values.

For the sake of brevity, the orientations described herein, such as top, bottom, up, down, above, below, side, etc., are all described with reference to the directions shown in the figures. For example, when referring to an upper surface of a semiconductor substrate, it means the upper surface of the semiconductor substrate in the direction shown in the drawing, which may or may not be the surface for receiving light. Similarly, when referring to a lower surface of the semiconductor substrate, it mean the lower surface of the semiconductor substrate in the direction shown in the drawing, which may or may not be the surface for receiving light.

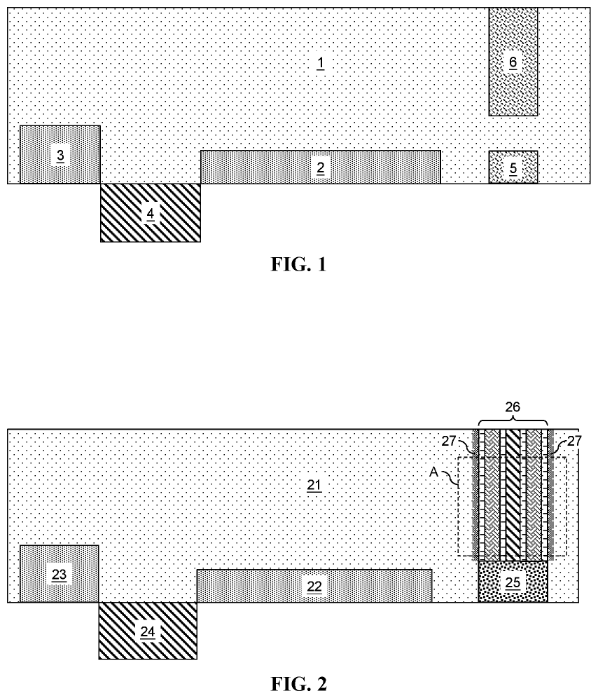

In a semiconductor substrate of a CMOS image sensor, a plurality of pixel units are generally arranged, each of which includes a photodiode and transistors associated with the photodiode. As shown in FIG. 1, a photodiode region 2 and a floating diffusion region 3 are formed in a semiconductor substrate 1, and a gate structure 4 is formed on a lower surface of the semiconductor substrate 1. Between adjacent devices (for example, between adjacent photodiodes, between adjacent transistors, or between a photodiode and an adjacent transistor, etc.), there are typically trench isolation structures (including deep trench isolation (DTI) structures 6 and shallow trench isolation (STI) structure 5) to prevent interference between devices. The inventors of the present disclosure have discovered by researching the prior art that some defects of these trench isolation structures, such as etch interface defects generated in the etching process for forming trenches, are liable to cause dark current.

Accordingly, in a first aspect of the present disclosure, there is provided an image sensor capable of reducing or eliminating dark current caused by an etch interface defect of a trench. An image sensor according to some embodiments of the present disclosure includes a trench isolation structure formed in a semiconductor substrate, wherein the trench isolation structure sequentially includes, from an outer portion to an inner portion of the trench isolation structure, a first oxide layer, a nitride layer, a second oxide layer and a semiconductor material layer that respectively extend in a thickness direction of the semiconductor substrate, such that a semiconductor-oxide-nitride-oxide-semiconductor (SONOS) structure is formed from the semiconductor substrate to the inner portion of the trench isolation structure via the outer portion of the trench isolation structure.

In some embodiments, as shown in FIG. 2, a photodiode region 22 and a floating diffusion region 23 are formed in a semiconductor substrate 21, and a gate structure 24 is formed on a lower surface of the semiconductor substrate 21. A first trench isolation structure 26 and a second trench isolation structure 25 are formed around the pixel unit (means being located around the pixel unit in a plan view that is parallel to a main surface of the image sensor). The first trench isolation structure 26 and the second trench isolation structures 25 have an overlapping portion in the plan view that is parallel to the main surface of the image sensor. The first trench isolation structure 26 is formed in a first trench that is located on an upper surface of the semiconductor substrate 21 and extends from the upper surface of the semiconductor substrate 21 toward the lower surface of the semiconductor substrate 21. The second trench isolation structure 25 is formed in a second trench that is located on the lower surface of the semiconductor substrate 21 and extends from the lower surface of the semiconductor substrate 21 toward the upper surface of the semiconductor substrate 21. Therein, a semiconductor-oxide-nitride-oxide-semiconductor structure is formed from the semiconductor substrate 21 through the outer portion of the first trench isolation structure 26 to the inner portion of the first trench isolation structure 26. Further, the semiconductor substrate 21 includes a region 27 which is formed by a collection of holes in the semiconductor substrate 21 around the first trench isolation structure 26.

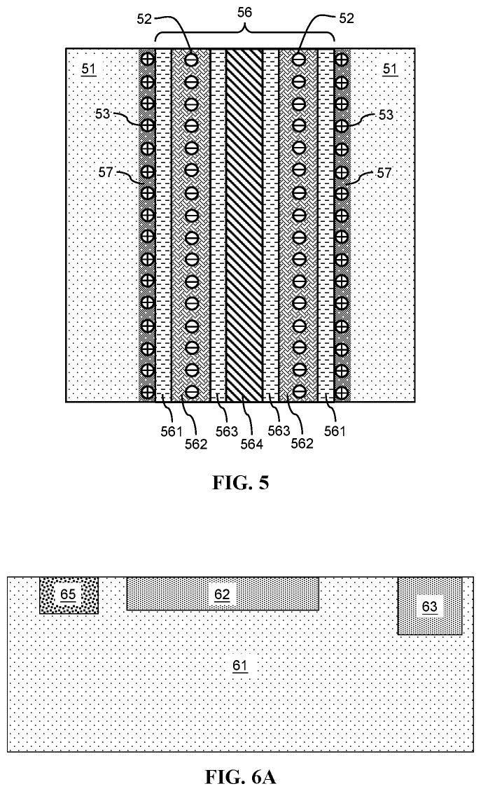

The structure of the area A of the image sensor in FIG. 2 is as shown in FIG. 5, wherein the portion of the first trench isolation structure 26 in the area A corresponds to the trench isolation structure 56 in FIG. 5, the portion of the region 27 in the area A corresponds to the region 57 in FIG. 5, and the portion of the semiconductor substrate 21 in the area A corresponds to the semiconductor substrate 51 in FIG. 5.

As shown in FIG. 5, the trench isolation structure 56 sequentially includes, from its outer portion to the inner portion, a first oxide layer 561, a nitride layer 562, and a second oxide layer 563 and the semiconductor material layer 564 that respectively extend in the thickness direction of the semiconductor substrate 51, such that the semiconductor substrate 51, the first oxide layer 561, the nitride layer 562, the second oxide layer 563, and the semiconductor material layer 564 are formed a semiconductor-oxide-nitride-oxide-semiconductor structure together (for example, in the direction from the left to the middle or from the right to the middle shown in FIG. 5). When a positive voltage relative to the semiconductor substrate 51 is applied to the semiconductor material layer 564, the electrons in the semiconductor substrate 51 tunnel into the first oxide layer 561 under the electric field and are trapped by the nitride layer 562. For example, reference numeral 52 denotes an electron trapped in the nitride layer 562. The second oxide layer 563 prevents the electrons that trapped in the nitride layer 562 from moving to the semiconductor material layer 564. The electrons trapped in the nitride layer 562 cause the nitride layer 562 to form a negative potential relative to the semiconductor substrate 51, and the holes in the semiconductor substrate 51 are collected near the first oxide layer 561 so as to form the region 57. For example, reference numeral 53 denotes a hole collected in the semiconductor substrate 51 near the first oxide layer 561.

Those skilled in the art will appreciate that the semiconductor substrate 51 and the semiconductor material layer 564 may be made of any semiconductor material (such as Si, Ge, SiGe, etc.) that is suitable for the semiconductor device. Further, the semiconductor substrate 51 may be a semiconductor portion of various composite substrates such as silicon-on-insulator (SOI) or silicon germanium-on-insulator. The semiconductor material layer 564 may comprise a polycrystalline semiconductor material. Those skilled in the art may appreciate that the materials of the semiconductor substrate 51 and the semiconductor material layer 564 are not limited by these examples and may be selected according to practical uses.

Referring again to FIG. 2, since the region 27 is a portion of the semiconductor substrate 21 that is located around the first trench isolation structure 26, the region 27 is located at or around the etch interface defects of the first trench. Thus, the holes in the region 27 may neutralize the electrons that may cause dark current due to etch interface defects of the first trench, thereby reducing or eliminating dark current. Since the region 27 is formed by the holes in the semiconductor substrate 21 being collected near the first trench isolation structure 26, the density of holes in the region 27 is higher than the density of the holes in the portion of the semiconductor substrate 21 located around the region 27.

In some embodiments, the bottom of the first trench isolation structure 26 is in contact with the top of the second trench isolation structure 25. This helps to enhance the isolation from crosstalk between pixel units.

Although in the example shown in the drawings of the present disclosure, the first trench isolation structure 26 is formed from the upper surface of the semiconductor substrate 21, the second trench isolation structure 25 is formed from the lower surface of the semiconductor substrate 21. However, those skilled in the art will appreciate that other situations are also feasible. Although in the example shown in the drawings of the present disclosure, the depth of the first trench isolation structure 26 is greater than the depth of the second trench isolation structure 25, those skilled in the art will appreciate that other situations are also feasible. In some embodiments, the upper surface of the semiconductor substrate 21 is closer to the surface of the image sensor for receiving light than the lower surface of the semiconductor substrate 21, but those skilled in the art will appreciate that other situations are also feasible.

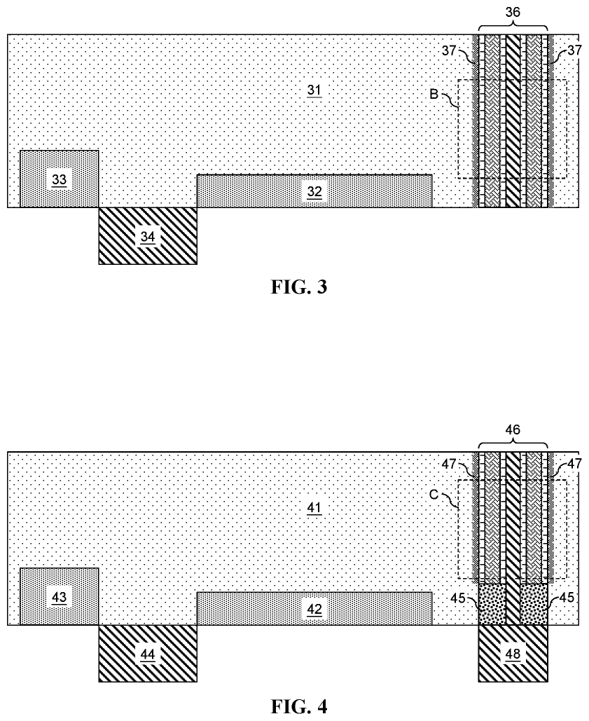

In some embodiments, the configuration of a portion of an image sensor is as shown in FIG. 3. The image sensor includes a semiconductor substrate 31 in which a photodiode region 32 and a floating diffusion region 33 are formed, and a gate structure 34 is formed on a lower surface of the semiconductor substrate 31. A trench isolation structure 36 is formed around the pixel unit. Here, the trench isolation structure 36 extends from the upper surface of the semiconductor substrate 31 toward the lower surface of the semiconductor substrate 31 and is exposed to the lower surface of the semiconductor substrate 31. A semiconductor-oxide-nitride-oxide-semiconductor structure is formed from the semiconductor substrate 31 through the outer portion of the trench isolation structure 36 to the inner portion of the trench isolation structure 36. Further, the semiconductor substrate 31 includes a region 37 which is formed by a collection of holes in the semiconductor substrate 31 around the first trench isolation structure 36.

The structure of the area B of the image sensor in FIG. 3 is as shown in FIG. 5, wherein the portion of the trench isolation structure 36 in the area B corresponds to the trench isolation structure 56 in FIG. 5, the portion of the region 37 in the area B corresponds to the region 57 in FIG. 5, and the portion of the semiconductor substrate 31 in the area B corresponds to the semiconductor substrate 51 in FIG. 5. The structure in FIG. 5 is as described above.

Since the region 37 is a portion of the semiconductor substrate 31 that is located around the trench isolation structure 36, the region 37 is located at or around the etch interface defects of the trench isolation structure 36. Thus, the holes in the region 37 may neutralize the electrons that cause dark current due to etch interface defects of the first trench, thereby reducing or eliminating dark current. Since the region 37 is formed by the holes in the semiconductor substrate 31 being collected near the first trench isolation structure 36, the density of holes in the region 37 is higher than the density of the holes in the portion of the semiconductor substrate 31 located around the region 37.

In some embodiments, the configuration of a portion of an image sensor is as shown in FIG. 4. The image sensor includes a semiconductor substrate 41 in which a photodiode region 42 and a floating diffusion region 43 are formed, and a gate structure 44 is formed on a lower surface of the semiconductor substrate 41. A first trench isolation structure 46 and a second trench isolation structure 45 are formed around the pixel unit, and the first trench isolation structure 46 and the second trench isolation structure 45 have an overlapping portion in the plan view parallel to a main surface of the image sensor. The first trench isolation structure 46 is formed in the first trench located on the upper surface of the semiconductor substrate 41 and extends from the upper surface of the semiconductor substrate 41 toward the lower surface of the semiconductor substrate 41, and the second trench isolation structure 45 is formed in the second trench located on the lower surface of the semiconductor substrate 41 and extends from the lower surface of the semiconductor substrate 41 toward the upper surface of the semiconductor substrate 41. A semiconductor-oxide-nitride-oxide-semiconductor structure is formed from the semiconductor substrate 41 through the outer portion of the first trench isolation structure 46 to the inner portion of the first trench isolation structure 46. Further, the semiconductor substrate 41 includes a region 47 which is formed by a collection of holes in the semiconductor substrate 41 around the first trench isolation structure 46.

The structure of the area C of the image sensor in FIG. 4 is as shown in FIG. 5, wherein the portion of the trench isolation structure 46 in the area C corresponds to the trench isolation structure 56 in FIG. 5, the portion of the region 47 in the area C corresponds to the region 57 in FIG. 5, and the portion of the semiconductor substrate 41 in the area C corresponds to the semiconductor substrate 51 in FIG. 5. The structure in FIG. 5 is as described above.

The image sensor according to these embodiments further includes an electrode portion 48 formed on the lower surface of the semiconductor substrate 41. The electrode portion 48, the first trench isolation structure 46 and the second trench isolation structure 45 have an overlapping portion in the plan view parallel to a main surface of the image sensor. A semiconductor material layer (corresponding to the portion indicated by reference numeral 564 in FIG. 5) extends from the upper surface of the semiconductor substrate 41 toward the lower surface of the semiconductor substrate 41 until passing through the second trench isolation structure 45 and being exposed to the lower surface of the semiconductor substrate 41 so as to be electrically connected to the electrode portion 48 located on the lower surface of the semiconductor substrate 41. The electrode portion 48 may include a polycrystalline semiconductor material electrically connected to a metal interconnect layer (not shown) through a conductive contact (not shown) to facilitate applying a voltage to the semiconductor material layer of the first trench isolation structure 46 through the metal interconnect layer, the conductive contact and the electrode portion 48.

Since the region 47 is a portion of the semiconductor substrate 41 that is located around the trench isolation structure 46, the region 47 is located at or around the etch interface defects of the trench isolation structure 46. Thus, the holes in the region 47 may neutralize the electrons that cause dark current due to etch interface defects of the first trench, thereby reducing or eliminating dark current. Since the region 47 is formed by the holes in the semiconductor substrate 41 being collected near the first trench isolation structure 46, the density of holes in the region 47 is higher than the density of the holes in the portion of the semiconductor substrate 41 located around the region 47.

In some embodiments, the bottom of the first trench isolation structure 46 is in contact with the top of the second trench isolation structure 45. This helps to enhance the isolation from crosstalk between pixel units.

Although in the example shown in the drawings of the present disclosure, the first trench isolation structure 46 is formed from the upper surface of the semiconductor substrate 41, the second trench isolation structure 45 is formed from the lower surface of the semiconductor substrate 41. However, those skilled in the art will appreciate that other situations are also feasible. Although in the example shown in the drawings of the present disclosure, the depth of the first trench isolation structure 46 is greater than the depth of the second trench isolation structure 45, those skilled in the art will appreciate that other situations are also feasible. In some embodiments, the upper surface of the semiconductor substrate 41 is closer to the surface of the image sensor for receiving light than the lower surface of the semiconductor substrate 41, but those skilled in the art will appreciate that other situations are also feasible.

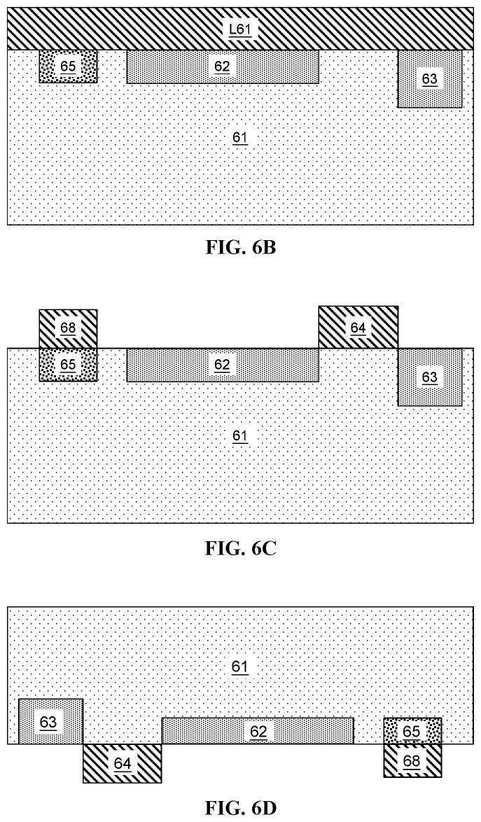

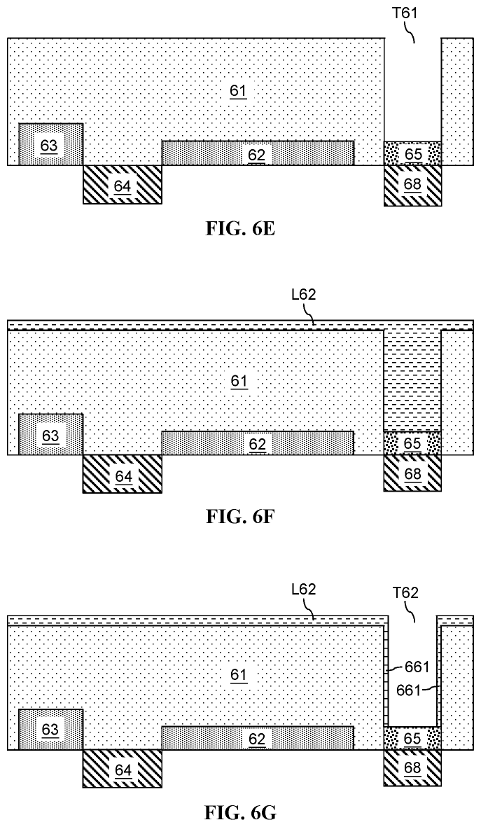

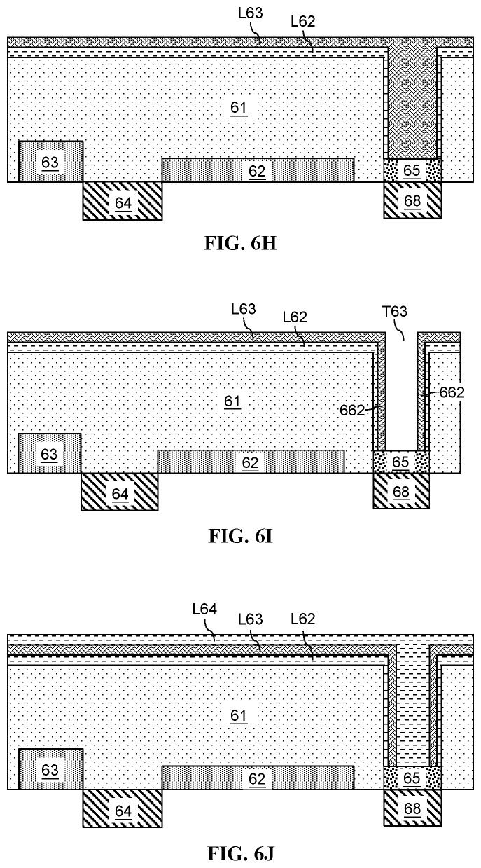

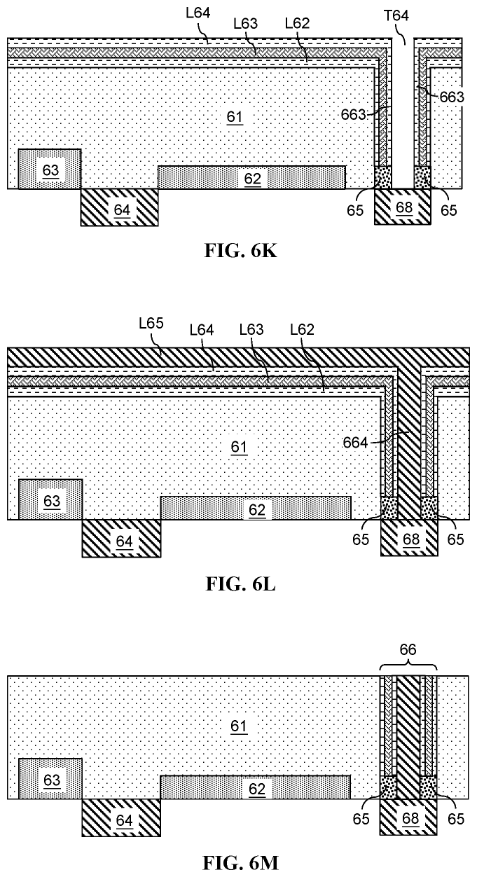

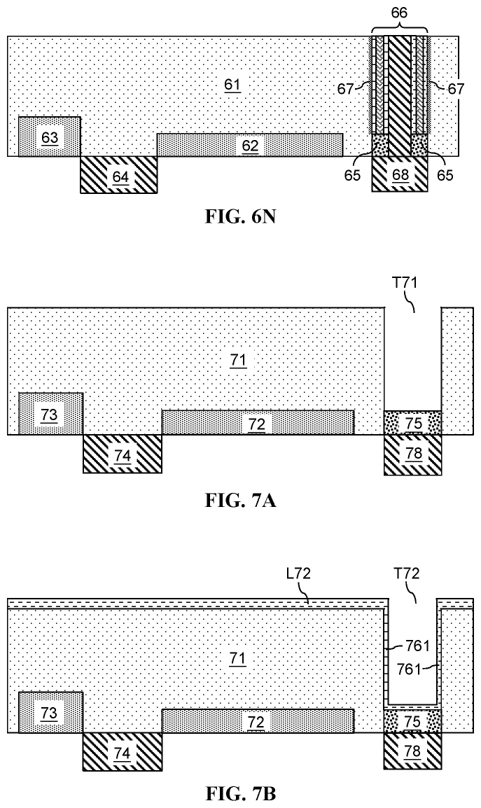

A method for manufacturing an image sensor according to one or more exemplary embodiments of the present disclosure is described below with reference to FIGS. 6A through 6N. The method for manufacturing an image sensor according to these embodiments is capable of manufacturing an image sensor similar to that shown in FIG. 4.

As shown in FIG. 6A, by operating from a surface (referred to as a lower surface in steps that are described with reference to FIGS. 6D through 6N) of the semiconductor substrate 61, a second trench isolation structure 65, a photodiode region 62 and a floating diffusion region 63 are formed in the semiconductor substrate 61. As shown in FIG. 6B, a conductive layer L61 covering the surface of the semiconductor substrate 61 is formed above the surface of the semiconductor substrate 61. For example, the conductive layer L61 may be formed of a polycrystalline semiconductor material. The conductive layer L61 is etched as shown in FIG. 6C, such that a gate structure 64 for the photodiode region 62 and the floating diffusion region 63, and an electrode portion 68 covering the second trench isolation structure 65 are formed. The wafer of the image sensor is turned over so that the top surface is facing downward as shown in FIG. 6D. The following steps are operated from the other surface (referred to as an upper surface in steps that are described with reference to FIGS. 6D through 6N) of the semiconductor substrate 61.

It will be appreciated by those skilled in the art that before the wafer is turned over as shown in FIG. 6D, the following processes may have been performed: forming transistors in the semiconductor substrate 61, forming conductive contacts, metal interconnection layers and interlayer dielectric layers on the surface of the semiconductor substrate 61, bonding the device wafer including the semiconductor substrate 61 and a carrier wafer, and thinning the semiconductor substrate 61, and the like.

As shown in FIG. 6E, a trench T61 is formed by operating from the upper surface of the semiconductor substrate 61. In the example shown in the drawings, the trench T61 is formed around the pixel unit. Those skilled in the art will appreciate, in other embodiments, that the trench T61 may be formed between any two adjacent devices or around any one of the devices. It will be appreciated by those skilled in the art that in the above description, the trench T61 may be located around the pixel unit, between two adjacent devices, or around a device in a plan view that is parallel to the main surface of the image sensor. For example, the trench T61 may be formed by photolithography and etching process. The etching process for forming the trench T61 may be a dry etching process.

As shown in FIG. 6F, an oxide layer L62 filling the trench T61 is formed by depositing an oxide from the upper surface of the semiconductor substrate 61. Although the oxide layer L62 illustrated in FIG. 6F fully fills the trench T61, it will be appreciated by those skilled in the art that the oxide layer L62 does not have to fully fill the trench T61 and only needs to cover walls of the trench T61. Since an oxygen source is introduced during forming the oxide layer L62, some etching defects at the walls of the trench T61 may be repaired by the oxygen source, which is advantageous for improving the wall morphology of the trench T61.

As shown in FIG. 6G, a portion of the oxide layer L62 that is in the middle of the trench T61 is removed, by etching from the upper surface of the semiconductor substrate 61, so as to form a trench T62. A portion of the oxide layer L62 at walls of the trench T61 is left so as to form a first oxide layer 661 of a first trench isolation structure 66. In the etching process in this step, the second trench isolation structure 65 may be an etch stop layer, such that there is no oxide (e.g., a part of the oxide layer L62) in the bottom of the trench T62. It will be appreciated by those skilled in the art, in other embodiments, that in the etching process in this step, the depth of the trench T62 may be controlled by controlling the etching time. The bottom of the trench T62 may reach or not reach the second trench isolation structure 65, that is, there may be some oxide or no oxide in the bottom of the trench T62.

As shown in FIG. 6H, a nitride layer L63 filling the trench T62 is formed by depositing a nitride from the upper surface of the semiconductor substrate 61. Although the nitride layer L63 illustrated in FIG. 6H fully fills the trench T62, it will be appreciated by those skilled in the art that the nitride layer L63 does not have to fully fill the trench T62 and only needs to cover walls of the trench T62 with one or more certain thicknesses.

As shown in FIG. 6I, a portion of the nitride layer L63 that is in the middle of the trench T62 is removed, by etching from the upper surface of the semiconductor substrate 61, so as to form a trench T63. A portion of the nitride layer L63 at walls of the trench T62 is left so as to form a nitride layer 662 of the first trench isolation structure 66. In the etching process in this step, the second trench isolation structure 65 may be an etch stop layer, such that there is no nitride (e.g., a part of the nitride layer L63) in the bottom of the trench T63. It will be appreciated by those skilled in the art, in other embodiments, that in the etching process in this step, the depth of the trench T63 may be controlled by controlling the etching time. The bottom of the trench T63 may reach or not reach the second trench isolation structure 65, that is, there may be some nitride or no nitride in the bottom of the trench T63.

As shown in FIG. 6J, an oxide layer L64 filling the trench T63 is formed by depositing an oxide from the upper surface of the semiconductor substrate 61. Although the oxide layer L64 illustrated in FIG. 6J fully fills the trench T63, it will be appreciated by those skilled in the art that the oxide layer L64 does not have to fully fill the trench T63 and only needs to cover walls of the trench T63 with one or more certain thicknesses.

As shown in FIG. 6K, a portion of the oxide layer L64 that is in the middle of the trench T63 is removed, by etching from the upper surface of the semiconductor substrate 61, so as to form a trench T64. A portion of the oxide layer L64 at walls of the trench T63 is left so as to form a second oxide layer 663 of the first trench isolation structure 66. The etching process in this step also removes a portion of the second trench isolation structure 65 and stops at the top of the electrode portion 68, which allows the trench T64 to pass through the second trench isolation structure 65 and to be formed as a via through the semiconductor substrate 61. At the bottom of the trench T64 is the electrode portion 68. In the etching process in this step, the electrode portion 68 may be used as an etch stop layer.

As shown in FIG. 6L, a polycrystalline semiconductor material layer L65 filling the trench T64 is formed by depositing a polycrystalline semiconductor material from the upper surface of the semiconductor substrate 61. Although the polycrystalline semiconductor material layer L65 illustrated in FIG. 6L fully fills the trench T64, it will be appreciated by those skilled in the art that the polycrystalline semiconductor material layer L65 does not have to fully fill the trench T64 and only needs to cover walls of the trench T64 with one or more certain thicknesses. The polycrystalline semiconductor material layer L65 that is filled in the trench T64 forms the semiconductor material layer 664 of the first trench isolation structure 66. Since at the bottom of the trench T64 is the electrode portion 68, the semiconductor material layer 664 filled in the trench T64 is in contact with the electrode portion 68, such that the semiconductor material layer 664 is electrically connected to the electrode portion 68. Accordingly, a positive voltage relative to the semiconductor substrate 61 may be applied to the semiconductor material layer 664 through metal interconnect layers (not shown), conductive contacts (not shown) and the electrode portion 68.

As shown in FIG. 6M, a planarization process is performed from the upper surface of the semiconductor substrate 61, for example, by an etching process and/or a chemical mechanical polishing (CMP) process so as to form the first trench isolation structure 66. The planarization process may facilitate forming other structures in and/or above the semiconductor substrate 61 in subsequent steps. All of the oxide layer L62, the nitride layer L63, the oxide layer L64, and the polycrystalline semiconductor material layer L65 that are above the upper surface of the semiconductor substrate 61 may be removed as shown in FIG. 6M. It will be appreciated by those skilled in the art that the planarization process may not remove or completely remove all of the layers above the upper surface of the semiconductor substrate 61, but merely flatten an upper surface of the structures that have been formed.

As shown in FIG. 6N, a positive voltage relative to the semiconductor substrate 61 is applied to the semiconductor material layer 664 through the metal interconnect layer, the conductive contacts and the electrode portion 68 such that electrons in the semiconductor substrate 61 pass through the first oxide layer 661 and are trapped in the nitride layer 662. The electrons trapped in the nitride layer 662 cause the nitride layer 662 to form a negative potential relative to the semiconductor substrate 61, such that holes in the semiconductor substrate 61 are collected near and around the first trench isolation structure 66 so as to form a region 67. The holes in the region 67 may neutralize electrons that may cause dark current due to etching defects of the trench T61, thereby reducing or eliminating dark current.

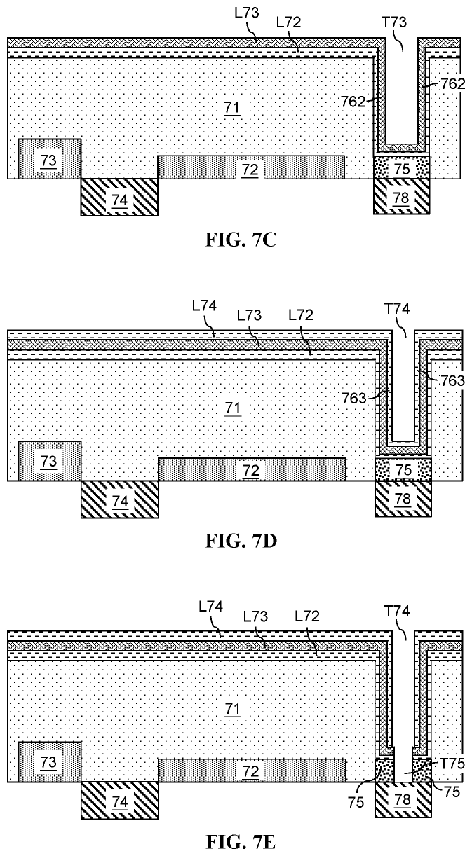

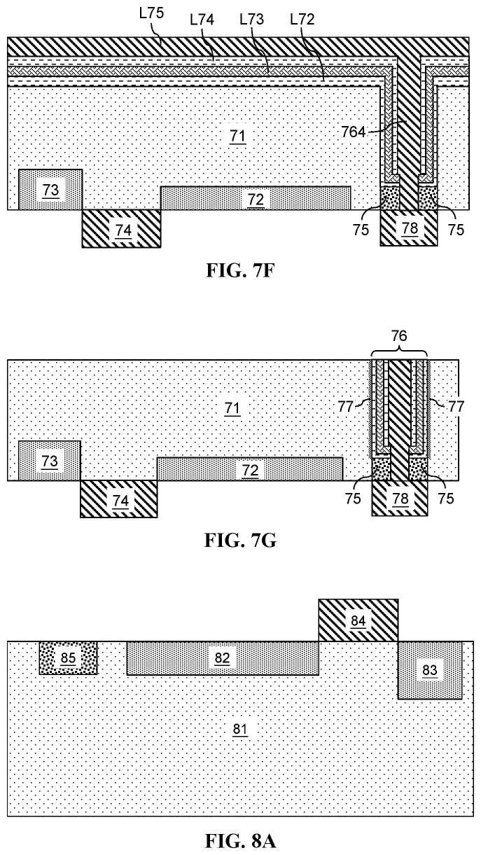

A method for manufacturing an image sensor according to one or more exemplary embodiments of the present disclosure is described below with reference to FIGS. 7A through 7G.

As shown in FIG. 7A, a trench T71 is formed by operating from the upper surface of the semiconductor substrate 71. The trench T71 is formed around the pixel unit. Those skilled in the art will appreciate, in other embodiments, that the trench T71 may be formed between any two adjacent devices or around any one of the devices. It will be appreciated by those skilled in the art that in the above description, the trench T71 may be located around the pixel unit, between two adjacent devices, or around a device in a plan view that is parallel to the main surface of the image sensor. For example, the trench T71 may be formed by photolithography and etching process. The etching process for forming the trench T71 may be a dry etching process.

It will be appreciated by those skilled in the art that before the step shown in FIG. 7A, the following processes (similar to the processes shown in FIGS. 6A through 6C) may have been performed: forming a second trench isolation structure 75, a photodiode region 72 and a floating diffusion region 73 in the semiconductor substrate 71 by operating from the lower surface of the semiconductor substrate 71; forming a gate structure 74 for the photodiode region 72 and the floating diffusion region 73, and an electrode portion 78 covering the second trench isolation structure 75; forming transistors in the semiconductor substrate 71; forming conductive contacts, metal interconnection layers and interlayer dielectric layers on the surface of the semiconductor substrate 71; bonding the device wafer including the semiconductor substrate 71 and a carrier wafer; and thinning the semiconductor substrate 71, and the like.

As shown in FIG. 7B, an oxide layer L72 filling the trench T71 is formed by depositing an oxide from the upper surface of the semiconductor substrate 71. The oxide layer L72 does not fully fill the trench T71, but covers walls of the trench T71 with one or more certain thicknesses. Since an oxygen source is introduced during forming the oxide layer L72, some etching defects at the walls of the trench T71 may be repaired by the oxygen source, which is advantageous for improving the wall morphology of the trench T71. The oxide layer L72 may be formed by a deposition process with good step coverage and/or conformality, for example, plasma enhanced chemical vapor deposition (PECVD) process, atomic layer deposition (ALD) process, plasma enhanced atomic layer deposition (PEALD) process, low temperature atomic layer deposition (soft ALD) process or the like. A portion of the oxide layer L72 located in the trench T71 is formed as the first oxide layer 761 of the first trench isolation structure 76. A portion of the trench T71 that is not filled with the oxide layer L72 is formed as a trench T72.

As shown in FIG. 7C, a nitride layer L73 filling the trench T72 is formed by depositing a nitride from the upper surface of the semiconductor substrate 71. The nitride layer L73 does not fully fill the trench T72, but covers walls of the trench T72 with one or more certain thicknesses. The nitride layer L73 may be formed by a deposition process with good step coverage and/or conformality, for example, plasma enhanced chemical vapor deposition (PECVD) process, atomic layer deposition (ALD) process, plasma enhanced atomic layer deposition (PEALD) process or the like. A portion of the nitride layer L73 located in the trench T72 is formed as a nitride layer 762 of the first trench isolation structure 76. A portion of the trench T72 that is not filled with the nitride layer L73 is formed as a trench T73.

As shown in FIG. 7D, an oxide layer L74 filling the trench T73 is formed by depositing an oxide from the upper surface of the semiconductor substrate 71. The oxide layer L74 does not fully fill the trench T73, but covers walls of the trench T73 with one or more certain thicknesses. The oxide layer L74 may be formed by a deposition process with good step coverage and/or conformality, for example, plasma enhanced chemical vapor deposition (PECVD) process, atomic layer deposition (ALD) process, plasma enhanced atomic layer deposition (PEALD) process or the like. A portion of the oxide layer L74 located in the trench T73 is formed as the second oxide layer 763 of the first trench isolation structure 76. A portion of the trench T73 that is not filled with the oxide layer L74 is formed as a trench T74.

As shown in FIG. 7E, at least a portion of the bottom of the trench T74 is etched from the upper surface of the semiconductor substrate 71, and the etching process is stopped at the top of the electrode portion 78. Accordingly, a via T75 through the bottom of the second oxide layer 763, the nitride layer 762 and the first oxide layer 761, and further through the second trench isolation structure 75 is formed. The via T75 connects the trench T74 to the electrode portion 78. Although in the example shown in FIG. 7E, the via T75 and the trench T74 have different sizes in a plan view parallel to the main surface of the image sensor, those skilled in the art will appreciate that the via T75 and the trench T74 may have the same size in the plan view.

As shown in FIG. 7F, a polycrystalline semiconductor material layer L75 filling the trench T74 is formed by depositing a polycrystalline semiconductor material from the upper surface of the semiconductor substrate 71. Although the polycrystalline semiconductor material layer L75 illustrated in FIG. 7F fully fills the trench T74, it will be appreciated by those skilled in the art that the polycrystalline semiconductor material layer L75 does not have to fully fill the trench T74 and only needs to cover walls of the trench T74 with one or more certain thicknesses. The polycrystalline semiconductor material layer L75 that is filled in the trench T74 and the via T75 forms the semiconductor material layer 764 of the first trench isolation structure 76. Since the via T75 connects the trench T74 to the electrode portion 78, the semiconductor material layer 764 filled in the trench T74 and the via T75 is in contact with the electrode portion 78, such that the semiconductor material layer 764 is electrically connected to the electrode portion 78.

As shown in FIG. 7G, a planarization process is performed from the upper surface of the semiconductor substrate 71, for example, by an etching process and/or a chemical mechanical polishing (CMP) process so as to form the first trench isolation structure 76. The planarization process may facilitate forming other structures in and/or above the semiconductor substrate 71 in subsequent steps. Further, a positive voltage relative to the semiconductor substrate 71 is applied to the semiconductor material layer 764 through the metal interconnect layer, the conductive contacts and the electrode portion 78 such that electrons in the semiconductor substrate 71 pass through the first oxide layer 761 and are trapped in the nitride layer 762. The electrons trapped in the nitride layer 762 cause the nitride layer 762 to form a negative potential relative to the semiconductor substrate 71, such that holes in the semiconductor substrate 71 are collected near and around the first trench isolation structure 76 so as to form a region 77. The holes in the region 77 may neutralize electrons that may cause dark current due to etching defects of the trench T71, thereby reducing or eliminating dark current.

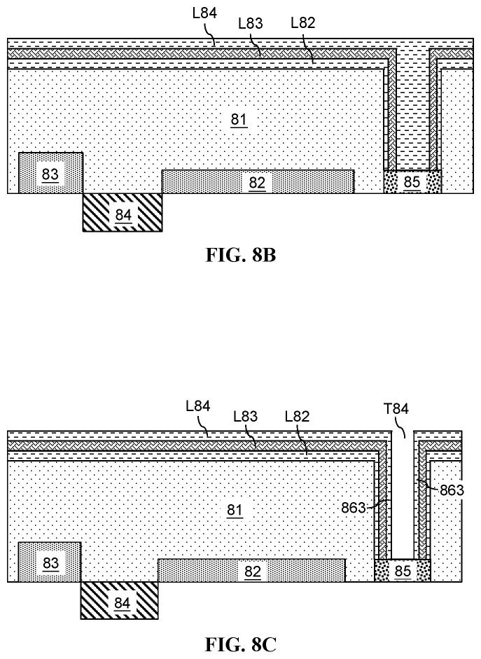

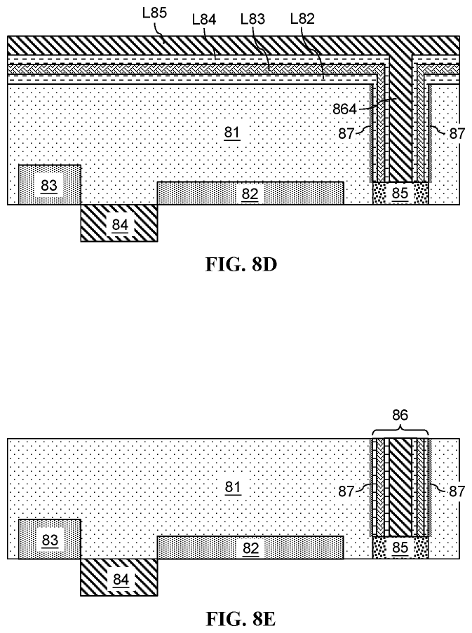

A method for manufacturing an image sensor according to one or more exemplary embodiments of the present disclosure is described below with reference to FIGS. 8A through 8E.

As shown in FIG. 8A, by operating from a surface (referred to as a lower surface in steps that are described with reference to FIGS. 8B through 8E) of the semiconductor substrate 81, a second trench isolation structure 85, a photodiode region 82 and a floating diffusion region 83 are formed in the semiconductor substrate 81, and a gate structure 84 for the photodiode region 82 and the floating diffusion region 83 is formed above the surface of the semiconductor substrate 81. After performing some other operations (refer to the operations described above before the wafer is turned over), the wafer is turned over so as to perform the operations described below.

As shown in FIG. 8B, deposition processes may be performed from the upper surface of the semiconductor substrate 81 to form an oxide layer L82, a nitride layer L83, and an oxide layer L84 covering the walls of the trench. The processes may be similar to those described above with reference to FIGS. 6E through 6J.

As shown in FIG. 8C, a portion of the oxide layer L84 that is in the middle of the trench is removed, by etching from the upper surface of the semiconductor substrate 81, so as to form a trench T84. A portion of the oxide layer L84 at walls of the trench is left so as to form a second oxide layer 863 of the first trench isolation structure 86. The etching in this step is stopped at the top of the second trench isolation structure 85, which makes at the bottom of the trench T84 is the second trench isolation structure 85.

As shown in FIG. 8D, a polycrystalline semiconductor material layer L85 filling the trench T84 is formed by depositing a polycrystalline semiconductor material from the upper surface of the semiconductor substrate 81. Although the polycrystalline semiconductor material layer L85 illustrated in FIG. 8D fully fills the trench T84, it will be appreciated by those skilled in the art that the polycrystalline semiconductor material layer L85 does not have to fully fill the trench T84 and only needs to cover walls of the trench T84 with one or more certain thicknesses. The polycrystalline semiconductor material layer L85 that is filled in the trench T84 forms the semiconductor material layer 864 of the first trench isolation structure 86. The polycrystalline semiconductor material layer L85 includes a first portion that is filled in the trench T84 (i.e., the semiconductor material layer 864) and a second portion that is above the upper surface of the semiconductor substrate 81. Since the first portion is in contact with the second portion of the polycrystalline semiconductor material layer L85, such that the first portion is electrically connected to the second portion of the polycrystalline semiconductor material layer L85. Thus, applying a positive voltage relative to the semiconductor substrate 81 to the semiconductor material layer 864 (i.e. the first portion of the polycrystalline semiconductor material layer L85) may be implemented, before the second portion of the polycrystalline semiconductor material layer L85 being removed, through applying a voltage to the second portion of the polycrystalline semiconductor material layer L85. Then a region 87 is formed in the semiconductor substrate 81 near and around the first trench isolation structure 86. The holes in the region 87 may neutralize electrons that may cause dark current due to etching defects of the trench, thereby reducing or eliminating dark current.

As shown in FIG. 8E, a planarization process is then performed from the upper surface of the semiconductor substrate 81, for example, by an etching process and/or a chemical mechanical polishing (CMP) process so as to form the first trench isolation structure 86. The planarization process may facilitate forming other structures in and/or above the semiconductor substrate 81 in subsequent steps.

The term “A or B” used through the specification refers to “A and B” and “A or B” rather than meaning that A and B are exclusive, unless otherwise specified.

The terms “front,” “back,” “top,” “bottom,” “over,” “under” and the like, as used herein, if any, are used for descriptive purposes and not necessarily for describing permanent relative positions. It should be understood that such terms are interchangeable under appropriate circumstances such that the embodiments of the disclosure described herein are, for example, capable of operation in other orientations than those illustrated or otherwise described herein.

The term “exemplary”, as used herein, means “serving as an example, instance, or illustration”, rather than as a “model” that would be exactly duplicated. Any implementation described herein as exemplary is not necessarily to be construed as preferred or advantageous over other implementations. Furthermore, there is no intention to be bound by any expressed or implied theory presented in the preceding technical field, background, summary or detailed description.

The term “substantially”, as used herein, is intended to encompass any slight variations due to design or manufacturing imperfections, device or component tolerances, environmental effects and/or other factors. The term “substantially” also allows for variation from a perfect or ideal case due to parasitic effects, noise, and other practical considerations that may be present in an actual implementation.

In addition, the foregoing description may refer to elements or nodes or features being “connected” or “coupled” together. As used herein, unless expressly stated otherwise, “connected” means that one element/node/feature is electrically, mechanically, logically or otherwise directly joined to (or directly communicates with) another element/node/feature. Likewise, unless expressly stated otherwise, “coupled” means that one element/node/feature may be mechanically, electrically, logically or otherwise joined to another element/node/feature in either a direct or indirect manner to permit interaction even though the two features may not be directly connected. That is, “coupled” is intended to encompass both direct and indirect joining of elements or other features, including connection with one or more intervening elements.

In addition, certain terminology, such as the terms “first”, “second” and the like, may also be used in the following description for the purpose of reference only, and thus are not intended to be limiting. For example, the terms “first”, “second” and other such numerical terms referring to structures or elements do not imply a sequence or order unless clearly indicated by the context.

Further, it should be noted that, the terms “comprise”, “include”, “have” and any other variants, as used herein, specify the presence of stated features, integers, steps, operations, elements, and/or components, but do not preclude the presence or addition of one or more other features, integers, steps, operations, elements, components, and/or groups thereof.

In this disclosure, the term “provide” is intended in a broad sense to encompass all ways of obtaining an object, thus the expression “providing an object” includes but is not limited to “purchasing”, “preparing/manufacturing”, “disposing/arranging”, “installing/assembling”, and/or “ordering” the object, or the like.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The description and drawings are, accordingly, to be regarded in an illustrative rather than in a restrictive sense.

Although some specific embodiments of the present disclosure have been described in detail with examples, it should be understood by a person skilled in the art that the above examples are only intended to be illustrative but not to limit the scope of the present disclosure. The embodiments disclosed herein can be combined arbitrarily with each other, without departing from the scope and spirit of the present disclosure. It should be understood by a person skilled in the art that the above embodiments can be modified without departing from the scope and spirit of the present disclosure. The scope of the present disclosure is defined by the attached claims.

What is claimed is:

1. An image sensor, comprising:
a semiconductor substrate; and
a trench isolation structure that is formed in the semiconductor substrate, wherein the trench isolation structure sequentially includes, from an outer portion to an inner portion of the trench isolation structure, a first oxide layer, a nitride layer, a second oxide layer and a semiconductor material layer that respectively extend in a thickness direction of the semiconductor substrate, such that a semiconductor-oxide-nitride-oxide-semiconductor structure is formed from the semiconductor substrate to the inner portion of the trench isolation structure via the outer portion of the trench isolation structure.

2. The image sensor according to claim 1, wherein the semiconductor substrate comprises one or more regions that are located around the trench isolation structure, wherein the one or more regions are formed by a collection of holes in the semiconductor substrate around the trench isolation structure.

3. The image sensor according to claim 2, wherein a density of holes in any of the one or more regions is higher than a density of holes in a portion of the semiconductor substrate that is located around the any of the one or more regions.

4. The image sensor according to claim 1, wherein the trench isolation structure is a first trench isolation structure that extends from a first surface of the semiconductor substrate to a second surface of the semiconductor substrate, wherein the second surface is opposite to the first surface, and the image sensor further comprises:
a second trench isolation structure having an overlapping portion with the first trench isolation structure in a plan view that is parallel to a main surface of the image sensor,
wherein a portion of the first trench isolation structure that is away from the first surface of the semiconductor substrate is in contact with a portion of the second trench isolation structure that is away from the second surface of the semiconductor substrate.

5. The image sensor according to claim 4, wherein the semiconductor material layer extends from the first surface of the semiconductor substrate toward the second surface of the semiconductor substrate until passing through the second trench isolation structure and being exposed to the second surface of the semiconductor substrate.

6. The image sensor according to claim 5, further comprising an electrode portion on the second surface of the semiconductor substrate, wherein the semiconductor material layer is electrically connected to the electrode portion, and the electrode portion is electrically connected to a metal in metal interconnect layers through one or more conductive contacts.

7. The image sensor according to claim 4, wherein the first surface of the semiconductor substrate is closer to a surface of the image sensor for receiving light, and the second surface of the semiconductor substrate is further from the surface of the image sensor for receiving light.

8. The image sensor according to claim 7, wherein a depth of the first trench isolation structure is greater than a depth of the second trench isolation structure.

9. The image sensor according to claim 1, wherein the semiconductor material layer comprises a polycrystalline semiconductor material.

10. The image sensor according to claim 6, wherein the electrode portion comprises a polycrystalline semiconductor material.

11. A method for manufacturing the image sensor, comprising:
providing a semiconductor substrate; and
forming a trench isolation structure in the semiconductor substrate by sequentially forming a first oxide layer, a nitride layer, a second oxide layer and a semiconductor material layer that respectively extend in a thickness direction of the semiconductor substrate, such that a semiconductor-oxide-nitride-oxide-semiconductor structure is formed from the semiconductor substrate to an inner portion of the trench isolation structure via an outer portion of the trench isolation structure.

12. The method according to claim 11, further comprising:
applying, to the semiconductor material layer, a positive voltage relative to the semiconductor substrate such that electrons in the semiconductor substrate pass through the first oxide layer and are trapped in the nitride layer, thereby holes in the semiconductor substrate are collected around the trench isolation structure so as to form one or more regions in the semiconductor substrate that are located around the trench isolation structure.

13. The method according to claim 11, wherein forming any layer of the first oxide layer, the nitride layer and the second oxide layer is by:
a conformal deposition process for forming the layer; or
a deposition process and an etching process for forming the layer.

14. The method according to claim 12, wherein the trench isolation structure is a first trench isolation structure which is formed from a first surface of the semiconductor substrate, the method further comprising:
forming a second trench isolation structure from a second surface of the semiconductor substrate, wherein the second surface is opposite to the first surface.

15. The method according to claim 14, wherein:
the second trench isolation structure is formed before the first trench isolation structure is formed, and
the first trench isolation structure is formed so that a portion of the first trench isolation structure that is away from the first surface of the semiconductor substrate is in contact with a portion of the second trench isolation structure that is away from the second surface of the semiconductor substrate.

16. The method according to claim 15, further comprising:
forming an electrode portion on the second surface of the semiconductor substrate after forming the second trench isolation structure and before forming the first trench isolation structure,
wherein the electrode portion has an overlapping portion with the second trench isolation structure in a plan view that is parallel to a main surface of the image sensor.

17. The method according to claim 16, wherein the semiconductor material layer in the first trench isolation structure is formed to be electrically connected to the electrode portion.

18. The method according to claim 17, wherein forming the first trench isolation structure comprises:
after forming the first oxide layer, the nitride layer and the second oxide layer, etching the second trench isolation structure from the first surface of the semiconductor substrate so as to form a via through the second trench isolation structure to expose the electrode portion to the first surface of the semiconductor substrate; and
depositing a polycrystalline semiconductor material into the via and to an inner side of the second oxide layer so as to form the semiconductor material layer that is electrically connected to the electrode portion and covers the second oxide layer.

19. The method according to claim 16, further comprising:
after forming the electrode portion, forming one or more conductive contacts that is electrically connected to the electrode portion; and
forming a metal in metal interconnect layers that is electrically connected to the one or more conductive contacts.

20. The method according to claim 19, wherein the positive voltage is applied via the metal in the metal interconnect layers, the one or more conductive contacts and the electrode portion.
